(19) United States
(12) Patent Application Publication
(10) Pub. No.: US 2022/0020857 A1
(43) Pub. Date: Jan. 20, 2022

(54) GATE CONTACT INTERLAYER FOR HEMT DEVICES WITH SELF-ALIGNED ELECTRODES

(71) Applicant: SEMICONDUCTOR COMPONENTS INDUSTRIES, LLC, Phoenix, AZ (US)

(72) Inventors: Aurore CONSTANT, Dudenaarde (BE); Peter COPPENS, Kanegejm (BE)

(73) Assignee: SEMICONDUCTOR COMPONENTS INDUSTRIES, LLC, Phoenix, AZ (US)

(21) Appl. No.: 16/948,785

(22) Filed: Oct. 1, 2020

Related U.S. Application Data
(60) Provisional application No. 62/705,766, filed on Jul. 15, 2020.

(51) Int. Cl. H01L 29/417; H01L 29/778; H01L 29/45; H01L 29/66

(52) U.S. Cl. CPC H01L 29/41783; H01L 29/66462; H01L 29/452; H01L 29/7783

(57) ABSTRACT

A HEMT is described in which a gate contact interlayer is included between a surface dielectric and a gate contact. Further, source, drain, and gate contacts may be self-aligned and formed using a single or same metal and metallization process. A gate may be formed in contact with, and covering a portion of, a barrier layer of the HEMT, with a gate contact formed in contact with the gate. The gate contact interlayer may be formed between a surface dielectric formed on the barrier layer and at least a portion of the gate contact.

### CROSS-REFERENCE TO RELATED APPLICATIONS

This application claims the benefit of U.S. Provisional Patent Application No. 62/705,766, filed on Jul. 15, 2020, the entire contents of which is incorporated herein by reference.

### TECHNICAL FIELD

This description relates to High Electron Mobility Transistors (HEMTs).

### BACKGROUND

A HEMT is a type of transistor that utilizes a current channel formed using a heterojunction at a boundary between two materials having different band gaps. For example, a relatively wide band gap material such as AlGaN (Aluminum Gallium Nitride) may be doped with n-type impurities and used to form a junction with an undoped, relatively narrow band gap material, such as GaN (Gallium Nitride). Then, an equilibrium is reached in which the narrow band gap material has excess majority carriers that form a 2-dimensional electron gas (2DEG). Consequently, and because the narrow band gap material has no doping impurities to disrupt current flow through scattering, HEMT devices provide, among other advantages, very high switching speeds, high gains, and high power applications.

### SUMMARY

According to one general aspect, a High Electron Mobility Transistor (HEMT) includes a source region, a source contact connected to the source region, a drain region, a drain contact connected to the drain region, a channel layer extending between the source region and the drain region, a barrier layer formed in contact with the channel layer, and extending between the source region and the drain region, a gate formed in contact with, and covering at least a portion of, the barrier layer, and a gate contact connected to the gate. A surface dielectric may be formed on the barrier layer, between the source contact and the gate contact, and between the drain contact and the gate contact, and a gate contact interlayer may be disposed between the surface dielectric and at least a portion of the gate contact.

According to another general aspect, a gate structure for a High Electron Mobility Transistor (HEMT) device includes a gate formed in contact with, and covering a portion of, a barrier layer of the HEMT, and a gate contact formed in contact with the gate. A gate contact interlayer may be formed between a surface dielectric formed on the barrier layer and at least a portion of the gate contact.

A method of making a High Electron Mobility Transistor (HEMT) may include forming a layer stack that includes at least a channel layer and a barrier layer adjacent to the channel layer and forming a heterojunction at which a current channel is defined in the channel layer between a source region and a drain region of the HEMT. The method may include forming a gate on the barrier layer, forming a surface dielectric on a portion of the gate, and on the barrier layer, and forming a contact interlayer on the surface dielectric. The method may include etching the surface dielectric to provide contact openings therein, etching the contact interlayer to form a gate contact interlayer disposed on the surface dielectric, and forming, in the contact openings, a source contact in contact with the source region, a drain contact in contact with the drain region, and a gate contact in contact with the gate and having at least a portion disposed on the gate contact interlayer.

The details of one or more implementations are set forth in the accompanying drawings and the description below. Other features will be apparent from the description and drawings, and from the claims.

### BRIEF DESCRIPTION OF THE DRAWINGS

FIG. 1 is a cross-section of a HEMT with a gate contact interlayer and self-aligned electrodes.

FIG. 2 is a cross section of a first example implementation of the HEMT of FIG. 1 using an Ohmic gate contact.

FIG. 3 is a cross section of a second example implementation of the HEMT of FIG. 1 using an Ohmic gate contact.

FIG. 4 is a cross section of a first example implementation of the HEMT of FIG. 1 using a Schottky gate contact.

FIG. 5 is a cross section of a second example implementation of the HEMT of FIG. 1 using a Schottky gate contact.

FIG. 6 is a flowchart illustrating example operations for forming a HEMT in accordance with the example embodiments of FIGS. 1-5.

FIGS. 7-11 illustrate cross-sections of example operations of a first process for forming a HEMT with a gate contact interlayer and self-aligned electrodes.

FIGS. 12-15 illustrate cross-sections of example operations of a second process for forming a HEMT with a gate contact interlayer and self-aligned electrodes.

FIG. 16 illustrates a cross-section of a first example operation of a first process for forming a HEMT with a gate contact interlayer without self-aligned electrodes.

FIG. 17 illustrates a cross-section of a second example operation of a first process for forming a HEMT with a gate contact interlayer without self-aligned electrodes.

FIG. 18 illustrates a cross-section of a third example operation of a first process for forming a HEMT with a gate contact interlayer without self-aligned electrodes.

FIG. 19 illustrates a cross-section of a fourth example operation of a first process for forming a HEMT with a gate contact interlayer without self-aligned electrodes.

FIG. 20 illustrates a cross-section of a fifth example operation of a first process for forming a HEMT with a gate contact interlayer without self-aligned electrodes.

FIG. 21 is a graph illustrating an example effect of the gate contact interlayer of FIG. 1 on contact resistance.

FIG. 22 is a graph illustrating current-voltage characteristics of example HEMT devices in accordance with described embodiments.

### DETAILED DESCRIPTION

As described in detail below, embodiments include a HEMT in which a gate contact interlayer is included between a surface dielectric and a gate contact. Further, source, drain, and gate contacts may be self-aligned and formed using a single or same metal and metallization process.

Such embodiments enable high temperature annealing for contact formation, while minimizing defects at metal and/or dielectric interfaces. Defects that might occur within the surface dielectric due to inter-diffusion may also be avoided. Accordingly, a smooth surface morphology is provided, a high degree of control of a gate field plate is enabled, and HEMT devices may be produced with a high yield rate.

Using self-aligned gate, source, and drain contacts with the same metal and metallization process enables all three contacts to be formed at a single level, thereby reducing a topography of HEMT devices. In such embodiments, resulting HEMT devices avoid a need for an alignment margin that would otherwise be required when using multiple metal layers for gate contacts and source/drain contacts, and associated lithography steps. As a result, for example, a required source-gate spacing may be reduced, resulting in smaller devices, and a greater number of devices formed during a given manufacturing process.

Additionally, described techniques enable gate contact formation as either a Schottky contact or an Ohmic contact. In conventional techniques, Ohmic gate contacts are difficult to manufacture. For example, Ohmic gate contacts may require expensive or rare materials, or materials that are not compatible with desired use case scenarios (e.g., may not be compatible with CMOS (complementary metal oxide semiconductor) device formation). Depending on materials being used, formation of conventional Ohmic gate contacts may either require low temperature annealing (which may be unsuitable for annealing of source/drain contacts), or high temperature annealing (which, as referenced above, leads to defects at a gate contact/surface dielectric interface in conventional settings).

In described embodiments, however, inclusion of the gate contact interlayer between the surface dielectric and the gate contact avoids such defects, and enables high temperature annealing, which may be as high as 900 C in some implementations. Consequently, Ohmic gate contacts may be formed using a wide range of materials and processes.

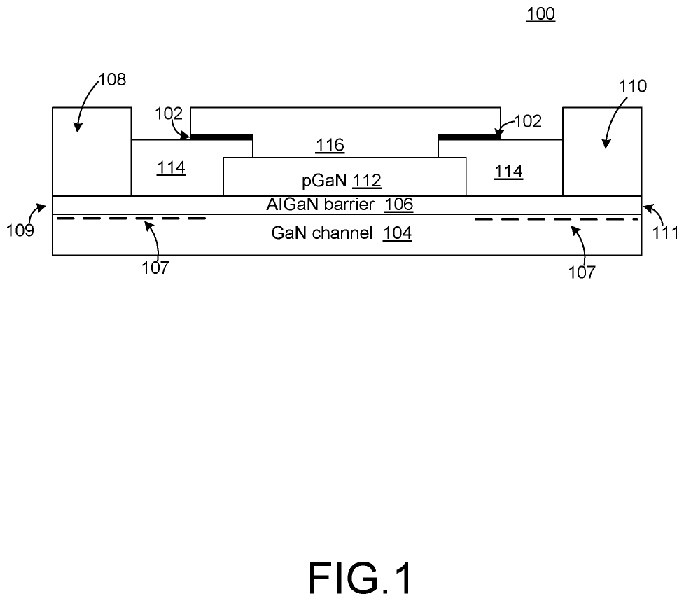

FIG. 1 illustrates a cross-section of a HEMT 100 with a gate contact interlayer 102 and self-aligned electrodes. In FIG. 1, a channel layer 104 is formed in contact with a barrier layer 106, and forms a heterojunction with the barrier layer 106. The heterojunction occurring at the interface of the channel layer 104 and the barrier layer 106 causes a channel region 107 that includes a 2DEG region of high electron mobility. For example, the channel layer 104 may be an undoped material with a relatively large width and relatively narrow bandgap energy (such as, e.g., Gallium Nitride, or GaN), while the barrier layer 106 may be a doped material with a relatively thin width and a relatively wide bandgap energy (such as, e.g., Aluminum Gallium Nitride, or AlGaN).

Further in FIG. 1, a source contact 108 is illustrated that provides electrical connection to an underlying source region 109, while a drain contact 110 similarly refers to a drain contact providing electrical connection to an underlying drain region 111 of the HEMT. During operation of the HEMT, current flows between the source contact 108 and the drain contact 110, by way of the source region 109, channel region 107, and drain region 111.

In general, due to the presence of the 2DEG referenced above, it is straightforward to form a ‘normally-on’ or depletion mode HEMT, in which source/drain current flows as a default state of the device. However, particularly for high power applications, a ‘normally-off’ or enhancement mode HEMT may be desired, in which the source/drain current is prohibited as a default state. In general, normally-off HEMTs may have an improved safety profile in high power applications, and may simplify related drive circuitry.

In FIG. 1, the HEMT is maintained in a normally-off state through the use of a gate 112, which is part of example gate structures that are described herein. That is, the HEMT of FIG. 1 may represent a normally-off device that prevents current flow through the channel region 107, unless the gate 112 is activated (e.g., biased).

For example, the gate 112 may be implemented as a p-type layer of GaN, also referred to as pGaN, which at least partially covers the barrier layer 106. For example, the pGaN layer 112 may be doped with Magnesium. The pGaN layer 112, barrier layer 106, and channel layer 104 may be understood to form a PIN (p-type, intrinsic, n-type) diode structure with a depletion zone that extends over the channel layer 104. This depletion zone disrupts the 2DEG of the channel region 107 in a default or unbiased state (e.g., V_{gs}=0V), but is rapidly removed by application of a positive bias at the gate 112, which thereby allows source-drain current to flow.

In FIG. 1, a surface dielectric 114 provides insulation, passivation, and separation with respect to a surface of the barrier layer 106, the source contact 108, the drain contact 110, and the gate 112. Although the surface dielectric 114 is illustrated in the simplified example of FIG. 1 as a single layer, two or more layers may be used in some example implementations. The gate contact interlayer 102 provides a barrier, e.g., a metal barrier layer, between at least a portion of the surface dielectric 114 and a gate contact 116.

Accordingly, as referenced above, it is possible to reduce, minimize, or eliminate defects that may otherwise occur in response to high-temperature annealing performed in conjunction with formation of the gate contact 116, the source contact 108, and the drain contact 110. For example, such defects may otherwise occur at the metal surface(s) of the gate contact 116, or within the surface dielectric 114 due to inter-diffusion.

Further, gate metal used as part of, or adjacent to, the gate contact 116 may be used to provide a gate field plate. Gate field plates may be used to control a breakdown voltage of the HEMT 100, but may have a detrimental effect on operating frequencies of the HEMT 100. Surface defects such as those referenced above may have a negative impact on an ability to control and define operational characteristics of such field plates, so that removal of such defects results in improved field plate control. Thus, for example, a central portion of the gate contact 116 may provide a gate electrode, while portions of the gate contact 116 extending toward the source contact 108 and/or the drain contact 110 may provide gate field plate(s), which benefit from the above-described effects.

The example HEMT 100 of FIG. 1 may be formed using a self-aligned process for the gate contact 116, the source contact 108, and the drain contact 110. That is, the gate contact 116, the source contact 108, and the drain contact 110 may be formed in a single lithography, using the same metal. As a result, as represented in FIG. 1, the gate contact 116, the source contact 108, and the drain contact 110 may be formed at a single level, reducing an overall topography of the HEMT 100. Moreover, a need for an alignment margin that would otherwise be required when using multiple metal layers (and associated lithography steps) is reduced. That is, in general, a lithographic alignment tolerance may be increased when structures, such as the gate contact 116, the source contact 108, and the drain contact 110 are forced into relative positions across multiple possible lithographically-defined positions, as shown and described below. As a result, for example, a required source-gate spacing may be reduced, resulting in smaller devices, and a greater number of devices formed during a given manufacturing process.

In FIG. 1, the gate contact interlayer 102 is illustrated between surfaces of the surface dielectric 114 and at least a portion(s) of the gate contact 116. In various implementations, some of which are illustrated and described below, the gate contact interlayer 102 may extend to all interfaces between the gate contact 116 and the surface dielectric 114, including vertical interfaces. Similarly, the gate contact interlayer 102 may extend between the gate contact 116 and the gate 112. Further, to the extent that the gate contact 116, the source contact 108, and the drain contact 110 are formed during a single metallization process, the gate contact interlayer 102 may also be formed between portions of the surface dielectric 114 and portions of either or both of the source contact 108 and the drain contact 110.

In particular, as described below, a resulting gate contact type may be formed as either a Schottky or an Ohmic contact. As referenced above, and described in detail, below, Ohmic contacts may be formed using readily available and compatible materials, such as Titanium-Aluminum based metallization, with a high thermal budget for annealing.

In FIG. 1, GaN channel layer 104, AlGaN barrier layer 106, channel 107, source region 109, and drain region 111 are illustrated and labeled separately. In the following figures and description of various HEMT configurations, these elements are not illustrated or labeled separately, but should be understood to be included.

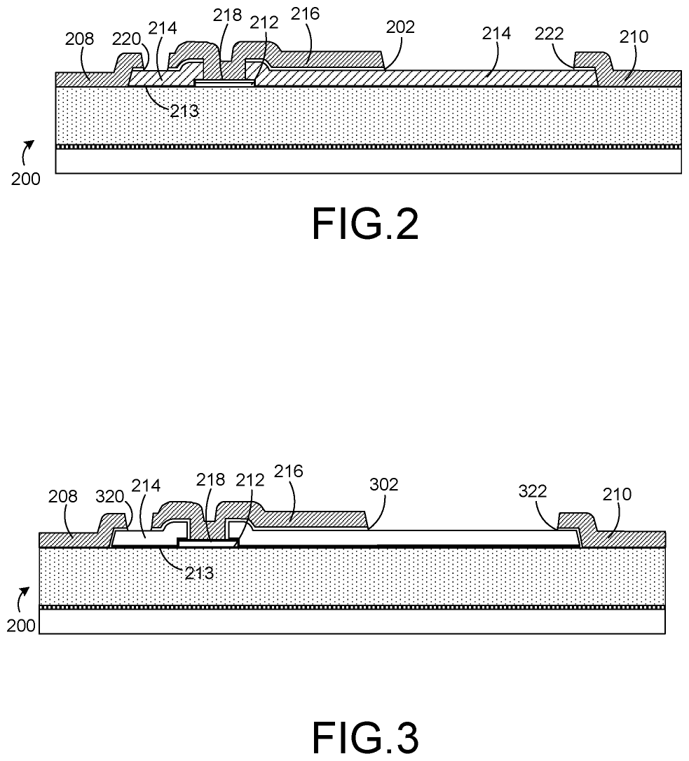

FIG. 2 is a cross section of a first example implementation of the HEMT of FIG. 1 using an Ohmic gate contact. In FIG. 2, a substrate 200 includes a layer stack that may be used to form the channel layer 104, the barrier layer 106, and the intervening channel 107, as well as source region 109 and drain region 111. These aspects are described above in conjunction with FIG. 1, and are not illustrated or described in detail in subsequent figures.

In FIG. 2, a gate contact interlayer 202 provides an example implementation of the gate contact interlayer 102 of FIG. 1. A source contact 208, a drain contact 210, and a gate 212 have a surface dielectric 213 and a surface dielectric 214 formed therebetween, which together at least partially covering the gate 212 and a surface of the substrate 200.

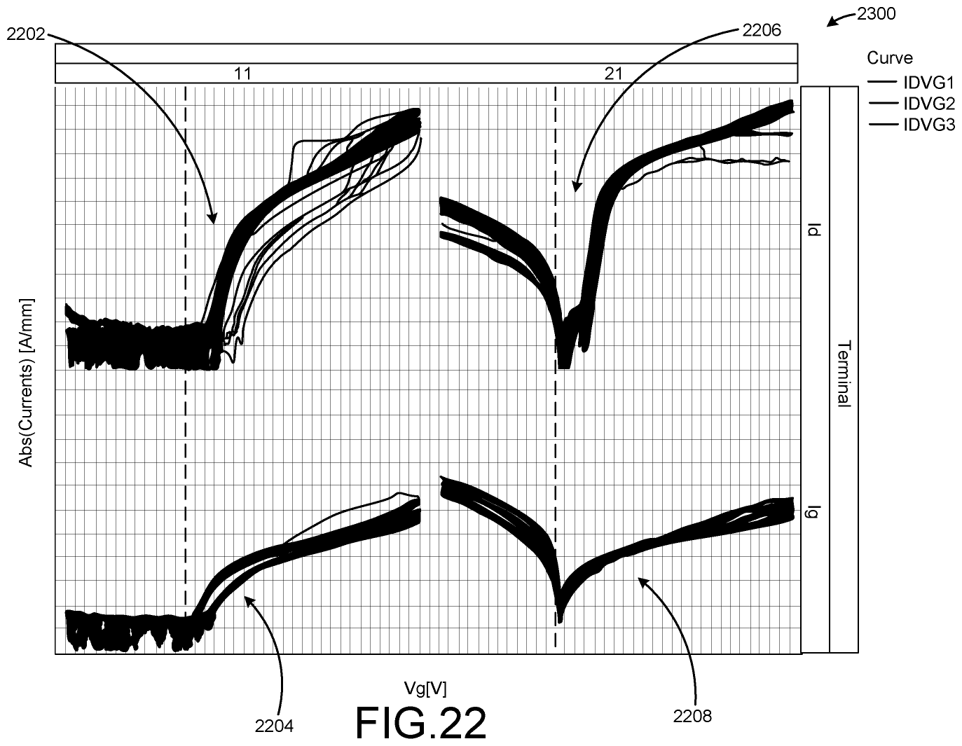

A gate contact 216 is formed on a treated layer 218 of the gate 212, where the treated layer 218 is used to facilitate the Ohmic nature of the Ohmic gate contact. In particular, as shown in FIG. 22, the Ohmic gate contact of FIG. 2 references a linear or near-linear voltage/current (resistance) for both positive and negative voltages at the gate 212/gate contact 216. In other words, the gate 212 and gate contact 216 are non-rectifying and gate current may exist for both positive and negative gate voltages.

To facilitate this effect with respect to the pGaN gate 212, a surface pre-treatment may be performed, as described in more detail, below. For example, an oxygen or nitrogen anneal may be performed. For example, an oxygen anneal may be used to reduce a p-type donor concentration in the treated layer 218. The anneal may lead to a depletion of nitrogen at the pGaN surface, thereby generating electrons, and thereby changing the pGaN surface into a depleted or n-type layer, referenced herein as the treated layer 218.

Further in FIG. 2, a source contact interlayer 220 is formed between a portion of the source contact 208 and the surface dielectric 214, while a drain contact interlayer 222 is formed between a portion of the drain contact 210 and the surface dielectric 214. The source contact interlayer 220 and the drain contact interlayer 222 may provide similar benefits as the gate contact interlayer 202, e.g., preventing defects at interface(s) with the surface dielectric 214 that may otherwise occur during high temperature annealing.

FIG. 3 is a cross section of a second example implementation of the HEMT of FIG. 1 using an Ohmic gate contact. In contrast with the example of FIG. 2, in FIG. 3, a source contact interlayer 320 is formed between all portions of the source contact 208 interfacing with the surface dielectric 214, e.g., including a first source contact interlayer portion between the source contact 208 and a dielectric surface parallel to a surface of the substrate 200, as well as a second source contact interlayer portion extending along a dielectric surface that connects the parallel surface and the substrate 200. A drain contact interlayer 322 is similarly formed between an entire interface of the drain contact 210 and the surface dielectric 214, e.g., including a first drain contact interlayer portion between the drain contact 210 and a dielectric surface parallel to a surface of the substrate 200, as well as a second drain contact interlayer portion extending along a dielectric surface that connects the parallel surface and the substrate 200. The source contact interlayer 320 and the drain contact interlayer 322 may thereby prevent defects at entire interface(s) thereof with the surface dielectric 214. Similarly, a gate contact interlayer 302 is formed between an entire surface of the interface between the gate contact 216 and the surface dielectric 214.

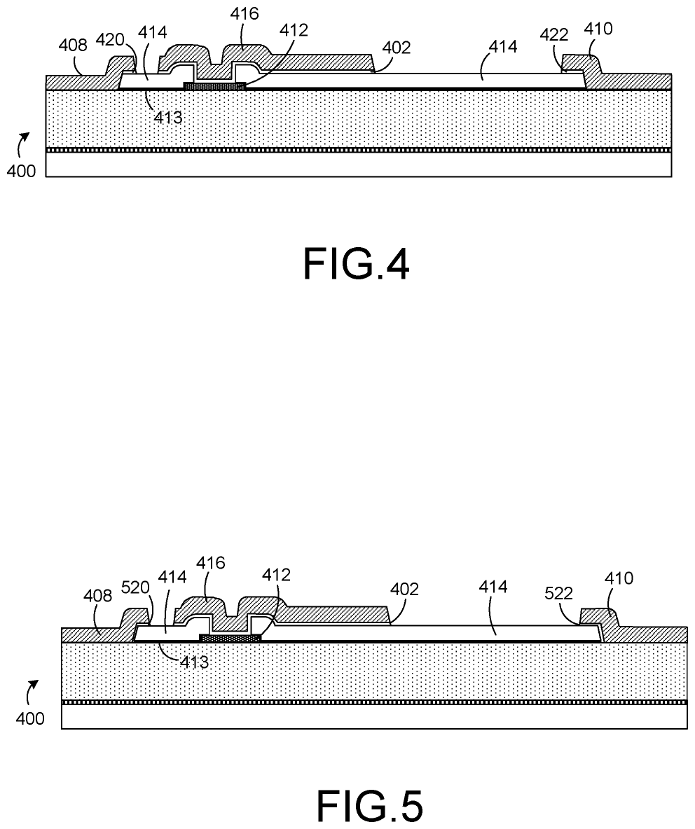

FIG. 4 is a cross section of a first example implementation of the HEMT of FIG. 1 using a Schottky gate contact. In FIG. 4, a gate contact interlayer 402 provides an example implementation of the gate contact interlayer 102 of FIG. 1. A source contact 408, a drain contact 410, and a gate 412 have a surface dielectric 413 and a surface dielectric 414 formed therebetween, which together at least partially cover the gate 412 and a surface of the substrate 400. A gate contact 416 is formed on the gate 412.

In FIG. 4, the gate contact interlayer 402 extends through an entire interface of the surface dielectric 414 and the gate contact 416. The gate contact interlayer 402 is also disposed between the gate contact 416 and the gate 412, thereby facilitating a rectified Schottky gate contact, as illustrated in FIG. 22.

Further in FIG. 4, a source contact interlayer 420 is formed between a portion of the source contact 408 and the surface dielectric 414, while a drain contact interlayer 422 is formed between a portion of the drain contact 410 and the surface dielectric 414. The source contact interlayer 420 and the drain contact interlayer 422 may provide similar benefits as the gate contact interlayer 402, e.g., preventing defects at interface(s) with the surface dielectric 414 that may otherwise occur during high temperature annealing.

FIG. 5 is a cross section of a second example implementation of the HEMT of FIG. 1 using a Schottky gate contact. In contrast with the example of FIG. 4, in FIG. 5, a source contact interlayer 520 is formed between all portions of the source contact 408 interfacing with the surface dielectric 414. A drain contact interlayer 522 is similarly formed between an entire interface of the drain contact 410 and the surface dielectric 414. The source contact interlayer 520 and the drain contact interlayer 522 may thereby prevent defects at entire interface(s) thereof with the surface dielectric 414.

In FIGS. 2-5, the various source/gate/drain metal layers may be formed in a self-aligned manner, using a single metallization. A single annealing process may be used for all three source/gate/drain contacts, with a high thermal budget of, e.g., 850 degrees. As referenced above, and illustrated in the examples, minimal source-gate spacing may be maintained.

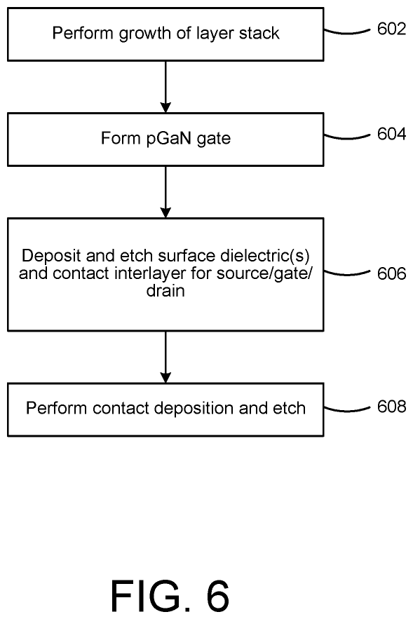

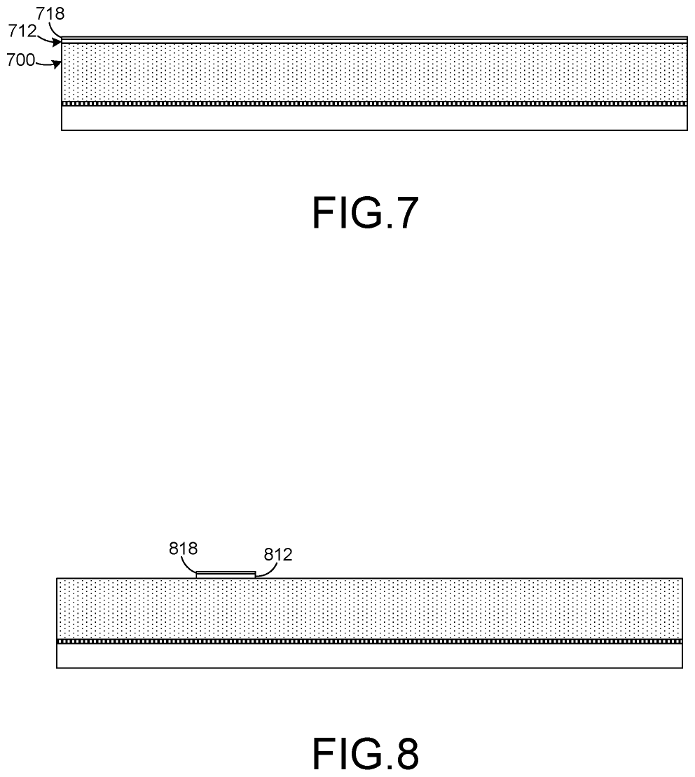

FIG. 6 is a flowchart illustrating example operations for forming, e.g., a method of making, a HEMT in accordance with the example embodiments of FIGS. 1-5. Various examples of implementations of FIG. 6 are illustrated and described below with respect to FIGS. 7-20.

In FIG. 6, growth of a layer stack may be performed (602). For example, the substrates 200/400 of FIGS. 2-5 may be formed, including implementations of the channel layer 104, barrier layer 106, and channel 107 of FIG. 1.

The layer stack may include, e.g., GaN, Si, Silicon Carbide (SiC), Aluminum Nitride (AlN), or Sapphire (e.g., monocrystalline Al₂O₃). The layer stack may include a buffer layer that may be advantageous in scenarios in which the device of FIG. 4 is used in high voltage contexts. For example, such a buffer layer may include carbon-doped Gallium Nitride (GaN). A strain relief layer may be included, if needed to facilitate strain relief with respect to any lattice mismatch that may occur. For example, if the above buffer layer is not used, a strain relief layer might be included adjacent to the channel layer 104. For example, a GaN channel layer has a non-trivial lattice mismatch with a substrate formed of Si. The resulting strain at the junction may be relieved, for example, by including GaN doped with a percentage of Al within an intervening strain relief layer.

A pGaN gate may then be formed (604). FIGS. 7 and 8 illustrate example processes for forming a pGaN gate, such as the gates 212/412 of FIGS. 1-5. As referenced with respect to FIGS. 2 and 3, and described below with respect to FIGS. 7 and 8, the pGaN gate may be treated with an annealing process to introduce donor states and facilitate formation of an Ohmic gate contact.

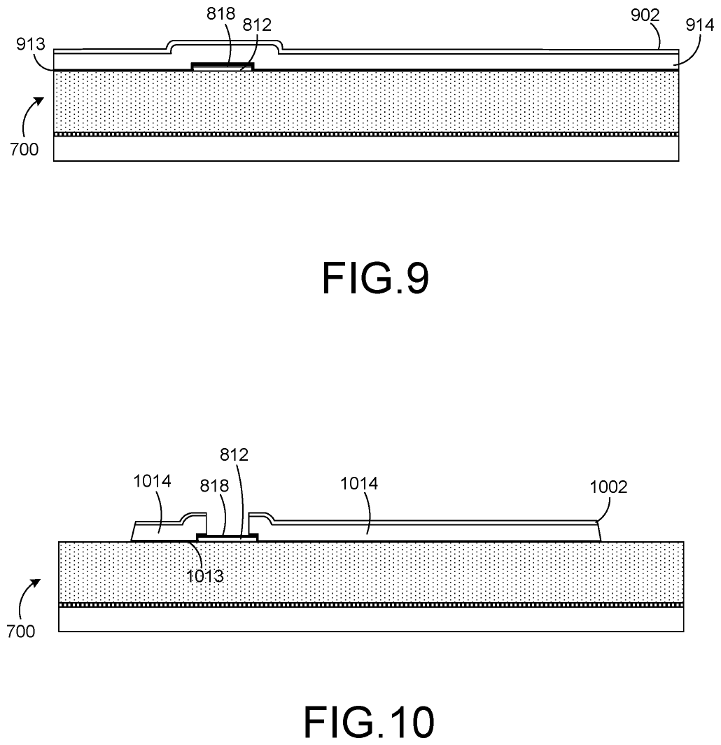

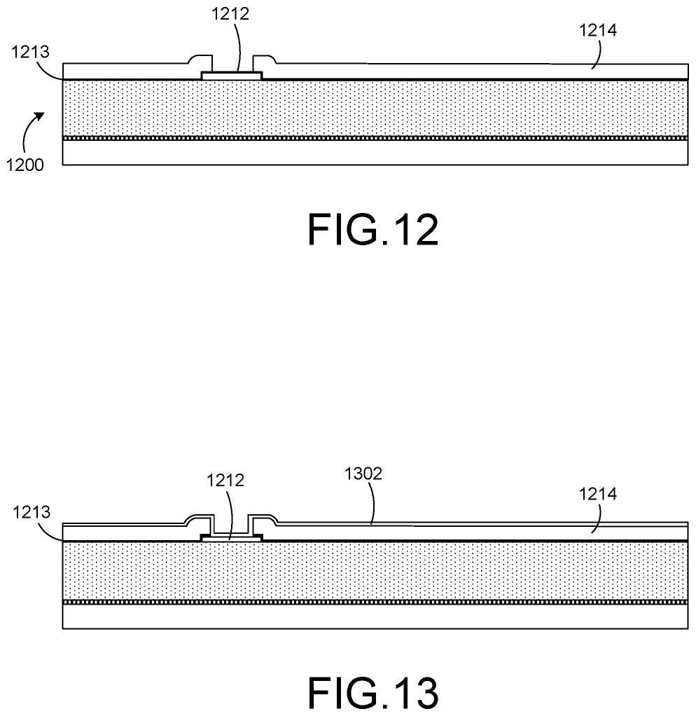

Further in FIG. 6, a surface dielectric(s) and contact interlayer may be deposited and etched (606). For example, both a surface dielectric and contact interlayer may be deposited and then etched together to form the Ohmic contacts of FIGS. 2 and 3, as shown in FIGS. 9 and 10. E.g., the contact interlayer may be formed prior to the etching of the surface dielectric. In other implementations, an initial etching may occur at the gate in between the forming of the surface dielectric and the contact interlayer, so as to expose the gate for formation of the contact interlayer directly thereon to form the Schottky contacts of FIGS. 4 and 5, as shown in FIGS. 12 and 13.

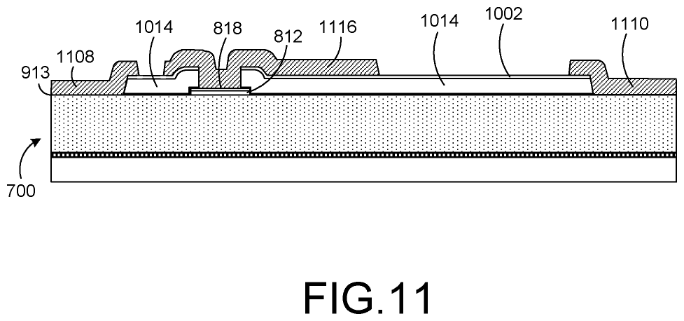

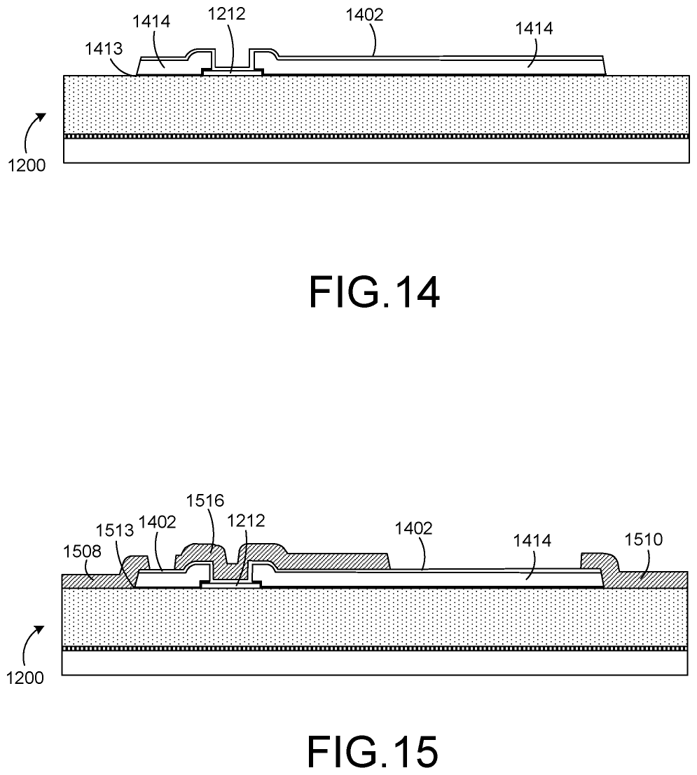

Finally in FIG. 6, contact deposition and etching may occur (608). For example, etching may occur through both the surface dielectric and contact interlayer for all of the source/gate/drain contacts, as shown in FIGS. 9 and 10, so that all of the source/gate/drain contacts may then be deposited, as shown in FIG. 11. In other examples, if the surface dielectric has already been etched to facilitate formation of the contact interlayer directly on the gate, then etching for the source and drain contact may proceed, followed by deposition of all of the source/gate/drain contacts, as shown in FIGS. 14 and 15. As referenced above, contact deposition may occur in a single annealing process with a high thermal budget of up to at least 850 C, and separate annealing processes for the source/drain contact and for the gate contact are not required.

FIGS. 7 and 8 illustrate a cross-section of first and second example operations of a first process for forming a HEMT with a gate contact interlayer and self-aligned electrodes. In FIG. 7, a substrate 700 has a pGaN layer 712 formed thereon, which is then treated with an annealing to form a treated layer 718 at the surface of the pGaN layer 712. The treated layer 718 may be formed as an intrinsic or n-doped layer to facilitate low contact resistance for an Ohmic gate contact. For embodiments in which a Schottky gate contact is formed, the treated layer 718 may be omitted.

In FIG. 8, etching is performed to leave only the gate 812 with treated layer 818, as shown. Etching may be end-pointed on an AlGaN layer at a surface of the substrate 700.

Then, in FIG. 9, one or more dielectric films may be deposited as the surface dielectric(s), shown in FIG. 9 as surface dielectrics 913 and 914. For example, a suitable oxide film may be used. Then a contact interlayer metal layer 902 may be deposited. For example, the contact interlayer may be formed as Titanium Nitride (TiN), or Tantalum Nitride (TaN).

In FIG. 10, etching of the contact openings proceeds, which reduces the surface dielectrics 1013, 1014, and the contact interlayer 1002. Accordingly, in FIG. 11, the source contact 1108, gate contact 1116, and drain contact 1110 are formed.

As described above, contact formation may proceed with a high thermal budget of up to, e.g., 800-850 C. The contact interlayer 1002 provides a barrier between the contacts 1108, 1110, 1116 and the surface dielectric 1014, and minimizes or prevents surface defects and interdiffusion. Remaining portions of the contact interlayer 1002 may be removed to provide the final device of FIG. 2, and to define the individual source contact interlayer 220, gate contact interlayer 202, and drain contact interlayer 222.

FIGS. 12-15 provide an example process flow according to FIG. 6, used to construct the Schottky gate contact embodiment of FIG. 4. In FIG. 12, it is assumed that a layer stack of a substrate 1200 has been formed, along with pGaN gate 1212. The processes of FIGS. 7 and 8 may be used, without requiring creation of the treated surface layer of the pGaN (718 in FIG. 7). In FIG. 12, surface dielectrics 1213, 1214 are formed, as well.

In FIG. 13, etching of the surface dielectrics 1213, 1214 occurs at the gate 1212. Contact interlayer 1302 may then be deposited on the surface dielectric 1214, as well as in contact with the gate 1212, as shown.

Accordingly, in FIG. 14, openings for source and drain contacts may be formed by etching through outer portions of the surface dielectrics 1213, 1214 and the contact interlayer 1202, to obtain etched surface dielectrics 1413, 1414 and etched contact interlayer 1402.

In this way, as described above, contact formation may proceed with a high thermal budget of up to, e.g., 800-850 C. The contact interlayer 1402 provides a barrier between the contacts 1508, 1510, 1516 and the surface dielectric 1414, and minimizes or prevents surface defects and interdiffusion. Remaining portions of the contact interlayer 1402 may be removed to provide the final device of FIG. 4, and to define the individual source contact interlayer 420, gate contact interlayer 402, and drain contact interlayer 422.

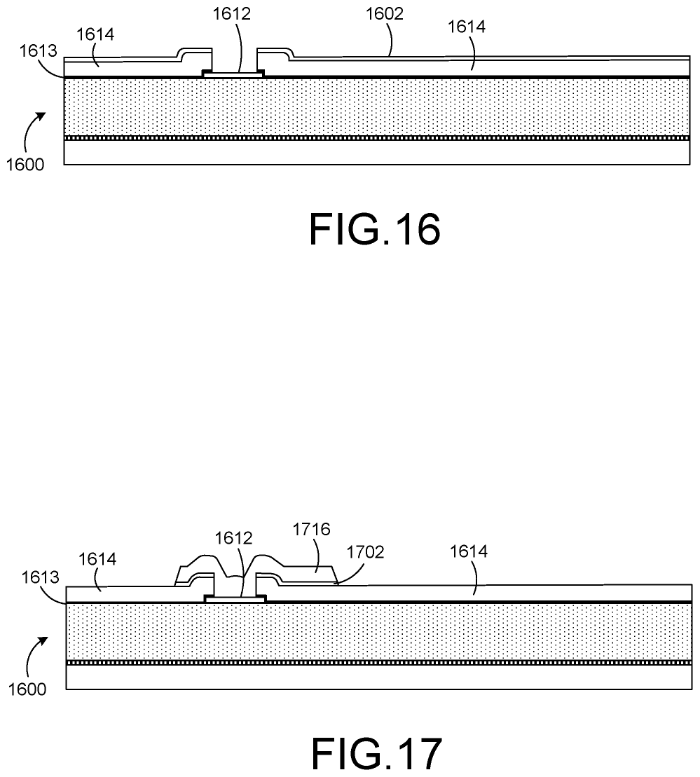

FIGS. 16-20 provide an example process flow, in which source/gate/drain contacts are not self-aligned, and are formed using different metal layers. In FIG. 16, stacked layers of substrate 1600 are formed. A gate 1612 is formed, and covered with surface dielectrics 1613 and 164, and by a contact interlayer 1602. Then, a gate contact opening is etched through the surface dielectrics 1613 and 164, and the contact interlayer 1602.

In FIG. 17, a gate contact 1716 is deposited. Not shown separately, a gate metal may be deposited onto the contact interlayer 1602, and then the gate metal and contact interlayer 1602 may be etched to provide the structure of FIG. 17, in which the gate contact 1716 has the gate contact interlayer 1702 as a barrier layer with the surface dielectric 1614, providing the above-described functions of preventing defects and interdiffusion at the interface of the gate contact 1716 and the surface dielectric 1614.

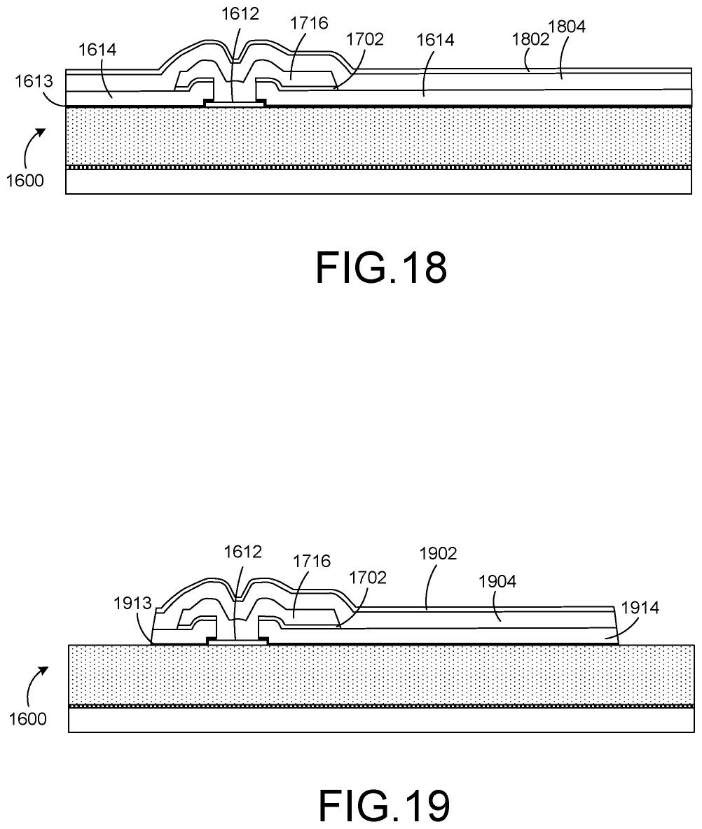

In FIG. 18, an additional dielectric layer 1804 is formed, followed by a second contact layer 1802. Source and drain contact openings are etched in FIG. 19, thereby leaving remaining source dielectrics 1904, 1913, 1914, and remaining contact interlayer 1902.

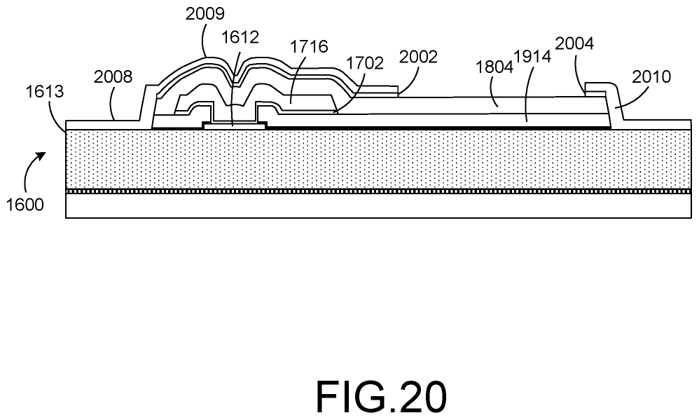

Then, in FIG. 20, the remaining contact interlayer 1902 is etched to leave a separate source field plate interlayer 2002 covered by a source field plate 2009 of a source contact 2008, as well as a separate drain contact interlayer 2004 covered by a portion of a drain contact 2010. In the embodiment of FIG. 20, although the source/gate/drain contacts are not self-aligned and are formed using separate metallizations, the contact interlayers 1702, 2002, 2004 provide similar benefits as described above, and the source field plate 2009 may provide enhanced control of a gate breakdown voltage of the illustrated device.

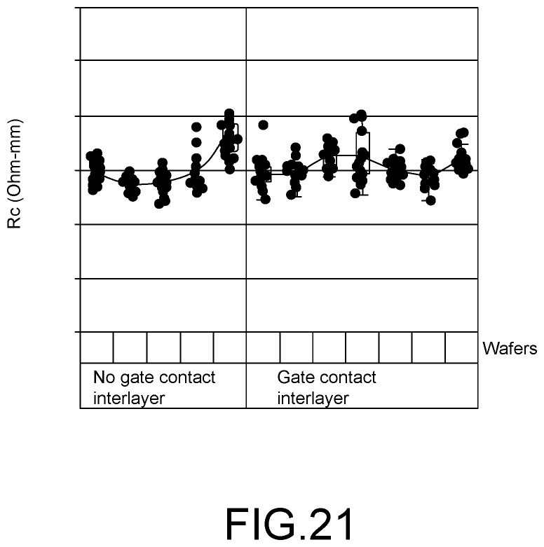

FIG. 21 is a graph illustrating an example effect of the gate contact interlayer of FIG. 1 on contact resistance. As illustrated, contact resistance is substantially similar across a plurality of wafers, both with and without a gate contact interlayer.

FIG. 22 is a graph illustrating current-voltage characteristics of example HEMT devices in accordance with described embodiments. Drain currents vs. gate voltages are shown for various implementations, in which curves 2202 and 2204 provide examples of Schottky gate contacts, while curves 2206 and 2208 illustrate examples of Ohmic gate contacts. As shown, the Schottky gate contacts 2202, 2204 are rectified, while the Ohmic gate contacts 2206, 2208 exhibit current flow under forward and reverse biases.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A High Electron Mobility Transistor (HEMT), comprising:
a source region;
a source contact connected to the source region;
a drain region;
a drain contact connected to the drain region;
a channel layer extending between the source region and the drain region;
a barrier layer formed in contact with the channel layer, and extending between the source region and the drain region;
a gate formed in contact with, and covering at least a portion of, the barrier layer;
a gate contact connected to the gate;
a surface dielectric formed on the barrier layer, between the source contact and the gate contact, and between the drain contact and the gate contact; and
a gate contact interlayer disposed between the surface dielectric and at least a portion of the gate contact.

2. The HEMT of claim 1, wherein the gate contact interlayer is disposed between the gate contact and the gate.

3. The HEMT of claim 1, wherein the gate contact forms an Ohmic contact with the gate.

4. The HEMT of claim 1, further comprising:
a source contact interlayer disposed between the source contact and the surface dielectric; and
a drain contact interlayer disposed between the drain contact and the surface dielectric.

5. The HEMT of claim 4, wherein the source contact interlayer is disposed along an entire interface of the source contact and the surface dielectric, and the drain contact interlayer is disposed along an entire interface of the drain contact and the surface dielectric.

6. The HEMT of claim 1, wherein the source contact, the drain contact, and the gate contact are self-aligned.

7. The HEMT of claim 1, wherein the source contact, the drain contact, and the gate contact are formed of the same metallization.

8. The HEMT of claim 1, wherein the gate contact interlayer includes a metal barrier layer.

9. The HEMT of claim 1, further comprising:
a second surface dielectric formed on the surface dielectric and on the gate contact;
a source field plate connected to the source contact that extends over at least a portion of the second surface dielectric and over at least a portion of the gate contact; and
a source field plate interlayer between the source field plate and the second surface dielectric.

10. A gate structure for a High Electron Mobility Transistor (HEMT) device, comprising:
a gate formed in contact with, and covering a portion of, a barrier layer of the HEMT;
a gate contact formed in contact with the gate; and
a gate contact interlayer formed between a surface dielectric formed on the barrier layer and at least a portion of the gate contact.

11. The gate structure of claim 10, wherein the gate contact interlayer is disposed between the gate contact and the gate.

12. The gate structure of claim 11, wherein the gate contact forms an Ohmic contact with the gate.

13. The gate structure of claim 12, wherein the gate includes pGaN, and a treated surface between the pGaN and the gate contact interlayer is treated to reduce a p-type donor concentration thereof.

14. The gate structure of claim 10, wherein the gate contact is self-aligned with a source contact and a drain contact of the HEMT.

15. The gate structure of claim 10, wherein the gate contact interlayer includes a metal barrier layer.

16. A method of making a High Electron Mobility Transistor (HEMT), comprising:
forming a layer stack that includes at least a channel layer and a barrier layer adjacent to the channel layer and forming a heterojunction at which a current channel is defined in the channel layer between a source region and a drain region of the HEMT;
forming a gate on the barrier layer;
forming a surface dielectric on a portion of the gate, and on the barrier layer;
forming a contact interlayer on the surface dielectric;
etching the surface dielectric to provide contact openings therein;
etching the contact interlayer to form a gate contact interlayer disposed on the surface dielectric; and
forming, in the contact openings, a source contact in contact with the source region, a drain contact in contact with the drain region, and a gate contact in contact with the gate and having at least a portion disposed on the gate contact interlayer.

17. The method of claim 16, wherein etching the surface dielectric comprises:
forming the contact interlayer prior to the etching the surface dielectric; and
etching the contact interlayer and the surface dielectric together to form the contact openings.

18. The method of claim 16, wherein etching the surface dielectric comprises:
etching the surface dielectric to form a gate contact opening of the contact openings;
forming the contact interlayer subsequent to the etching the surface dielectric; and
etching the contact interlayer to remove the contact interlayer from a source contact opening and a drain contact opening of the contact openings, while leaving the contact interlayer within the gate contact opening of the contact openings and disposed on the gate.

19. The method of claim 16, wherein the source contact, the drain contact, and the gate contact are formed using a self-aligned process and using the same metallization.

20. The method of claim 16, comprising:
forming a source contact interlayer disposed between the source contact and the surface dielectric; and
a drain contact interlayer disposed between the drain contact and the surface dielectric.
